(19) United States
(12) Patent Application Publication
(10) Pub. No.: US 2008/0217715 A1
(43) Pub. Date: Sep. 11, 2008

(54) Wafer Level Package Using Silicon Via Contacts for Cmos Image Sensor and Method of Fabricating the Same

(76) Inventors: Tae-Seok Park, Suwon-si (KR); Young Sung Kim, Yongin-si (KR)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 12/088,529

(22) PCT Filed: Oct. 11, 2005
(86) PCT No.: PCT/KR2005/003370

§ 371 Date: Mar. 28, 2008

(51) Int. Cl. H01L 31/0203; H01L 31/18

(52) U.S. Cl. 257/434; 438/64; 257/E31.111

(57) ABSTRACT

The present invention relates to a wafer level package of a CMOS image sensor using silicon via contacts and a method of manufacturing the same. A wafer level package of a CMOS image sensor includes: a wafer where image sensor elements including a plurality of electrode pads are formed; a transparent substrate attached to a front side of the wafer; a via hole formed from a back side of the wafer to underneath of a plurality of electrode pads of the front side; a passivation layer formed on a remaining portion except the underneath of the electrode pads in the via hole and whole back side of the wafer; a via contact formed in the via hole; and a solder bump formed on the via contact of the back side of the wafer.

### TECHNICAL FIELD

The present invention relates to a wafer level package of a complementary metal oxide semiconductor (CMOS) image sensor and a method of manufacturing the same; and, more particularly, to a wafer level package of a CMOS image sensor and a method of manufacturing the same by forming a front side of a wafer where image sensing elements including a sensing unit and an electrode pad are formed and forming a silicon via contact which directly attaches the electrode pad to a back side of the wafer and by forming a solder bump on an exposed silicon via contact of the back side of the wafer and attaching the solder bump to a printed circuit board (PCB).

### BACKGROUND ART

Generally, an image sensor is a semiconductor module for converting an optical image to an electric signal, and used to store an image signal and transfer it to a display device. The image sensor is roughly classified into two classes, i.e., one is a charge-coupled device (CCD) image sensor and the other is a CMOS image sensor. The CCD image sensor transfers an electric charge by continually controlling a depth of a potential well in the direction of the charge transfer. The CMOS image sensor performs an image sensing by using one or more transistor and a photo diode included in a pixel unit cell, wherein the photo diode acts as a photo sensor.

Since the CCD image sensor has less noise and better image quality in comparison with the CMOS image sensor, the CCD image sensor is suitable for a digital camera. On the contrary, the CMOS image sensor has generally less power consumption and lower manufacturing cost and can be easily integrated to a peripheral circuit chip in comparison with the CCD image sensor. Particularly, the CMOS image sensor can be produced using conventional technologies for manufacturing semiconductors, and it is easily integrated to a peripheral system which performs operations such as amplification and signal processing, resulting in a reduction of the manufacturing cost. Further, the CMOS image sensor has a high operational speed and power consumption of the CMOS image sensor is about 1% of that of the CCD image sensor. Therefore, the CMOS image sensor has been applied to a camera for a cellular phone and a personal digital assistant (PDA). However, as technology of the CMOS image sensor has been developed, the technical boundary between the CMOS image sensor and the CCD image sensor is demolished.

That is, the speed of technical development of the CMOS image sensor has been greatly increased. For instance, the CMOS image sensor was used as an image sensor for a VGA camera phone; however, recently, the CMOS image sensor is used as an image sensor for over 2-megapixel camera phone.

Meanwhile, until now, a modularization has been processed in the manner of wire bonding by using a package for an image sensor chip. However, according to the wire bonding process, the foreign materials are generated to cause an image defect of a sensor window, and so the production yield during module assembly is decreased and a depth, a width and a height of the module are increased, making it difficult to reduce a size of the module.

Recently, the chip on flexible PCB (COF) technology is beginning to be applied as a new method for modularizing cameras. Herein, the COF technology uses an anisotropic conductive film (ACF) which is applied to a technology for manufacturing a liquid crystal display (LCD) panel. The Korean patent application No. 2003-0069321 discloses the flip chip Au bumping process which finishes the packaging process at a wafer state, and also an imaging element package to which the COF mount technology is applied and the method for manufacturing the same.

FIG. 1 is a diagram showing a camera module using a CMOS image sensor (CIS) chip according to the prior art.

As shown in FIG. 1, bonding of a CIS chip 105 is completed by connecting a gold stud bump 120b formed on the CIS chip 105 to an external electrode pad 120a of a flexible printed circuit board (FPC) 103 through a conductive ball of an anisotropic conductive film 104. Thereafter, the camera module is completed by adding a lens 100, a lens housing 101 and an infrared filter (not shown). In this manner, the CIS chip 105 can be directly attached to the FPC 103 without an additional package for the CIS by using the anisotropic conductive film.

However, in the above-mentioned flip chip method, since a sensor window 106 for image sensing is inevitably faced to the anisotropic conductive film 104, the foreign materials generated from the anisotropic conductive film 104 and FPC enter the sensor window 106 of the CIS chip, when the CIS chip 105 is attached to the FPC 103. Therefore, the production yield is greatly decreased.

For solving the above-mentioned problem, Shellcase, an Israeli corporation, has developed a new technology. According to the technology of Shellcase, a wafer is etched and an electrode, which is connected to an electrode pad formed on the same surface that a sensing unit of the wafer is formed, is extended to the back side of the wafer (opposite side of the sensing unit) so that the sensing unit of CIS chip is directed to an opposite direction of an anisotropic film in order to be attached to an FPC.

FIGS. 2 to 6 are cross-sectional views showing the process of Shellcase for manufacturing the CIS package.

Referring to FIG. 2, through a predetermined manufacturing process, CIS elements such as an electrode pad 201 and a sensing unit 202 for image sensing are formed on a front side 200a of a wafer 200. After completing the process for manufacturing the image sensor package described below, chips are separated by dicing along a cutting lane 250.

Next, as shown in FIG. 3, a first glass substrate 204 is added on the front side of the wafer 200 by using an epoxy 203.

Next, referring to FIG. 4, after etching the wafer 200 from a back side 200b until the electrode pad 201 which exists on the front side of the wafer 200 is exposed as shown in a circle 206, a second glass substrate 207 is attached by using an epoxy 203a.

Next, as shown in FIG. 5, after etching the second glass substrate 207, an external electrode 208 is formed by forming and patterning an electric conductor. The external electrode 208 forms a T-contact 209 with the electrode pad 201.

Next, as shown in FIG. 6, after exposing a region, where a solder bump is to be formed, by depositing and patterning an insulating layer 211 on the second glass substrate 207 and the external electrode 208, a solder bump 210 is formed and chips are separated from one another by dicing the wafer 200 along the cutting lane 250. Thereafter, through a predetermined manufacturing process, an imaging device module such as a camera is assembled.

However, in the above-mentioned method for manufacturing image sensor package, a region of the T-contact 209 may be cracked and thus, a contact failure easily occurs. Further, the manufacturing process is complicated, e.g., a patterning process for forming an external electrode should be performed and an insulating layer for protecting an external electrode or for solder masking should be formed. Accordingly, a production yield is decreased.

### DISCLOSURE OF INVENTION

### Technical Problem

The present invention has been proposed in order to overcome the above-described problems in the related art. It is, therefore, an object of the present invention to prevent foreign materials from entering an image sensing unit.

It is another object of the present invention to provide a chip scale package of an image sensor having a thin image sensor module.

### Technical Solution

In accordance with one aspect of the present invention, there is provided a method of wafer level packaging of a CMOS image sensor, comprising the steps of: attaching a transparent substrate to a front side of a wafer where image sensor elements including a plurality of electrode pads are formed; grinding a back side of the wafer to remove an unnecessary part thereof; forming a via hole penetrating from the back side of the wafer to underneath of the plurality of electrode pads of the front side of the wafer; forming a passivation layer on whole surfaces of the via hole and the back side of the wafer; removing the passivation layer formed on the electrode pad; forming a via contact on the via hole by filling the via hole with metal; forming a solder bump on the via contact of the back side of the wafer; and dicing the wafer and the transparent substrate.

In accordance with another aspect of the present invention, there is provided a wafer level package of a CMOS image sensor, comprising: a wafer where image sensor elements including a plurality of electrode pads are formed; a transparent substrate attached to a front side of the wafer; a via hole formed from a back side of the wafer to underneath of a plurality of electrode pads of the front side of the wafer; a passivation layer formed on a remaining portion except the lower part of the electrode pads in the via hole and whole back side of the wafer; a via contact formed in the via hole; and a solder bump formed on the via contact of the back side of the wafer.

### BRIEF DESCRIPTION OF THE DRAWINGS

FIG. 1 is a diagram showing a camera module using a complementary metal oxide semiconductor (CMOS) image sensor (CIS) chip according to a prior art;

FIGS. 2 to 6 are cross-sectional views showing the process of Shellcase for manufacturing the CIS package; and

FIGS. 7 to 16 are cross-sectional views showing a method of wafer level packaging of a CMOS image sensor using silicon via contacts in accordance with the preferred embodiment of the present invention.

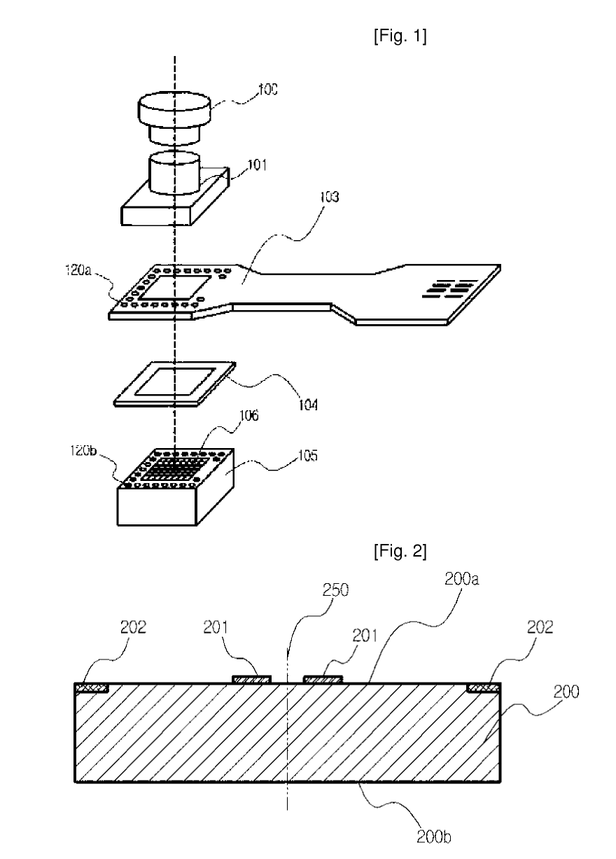

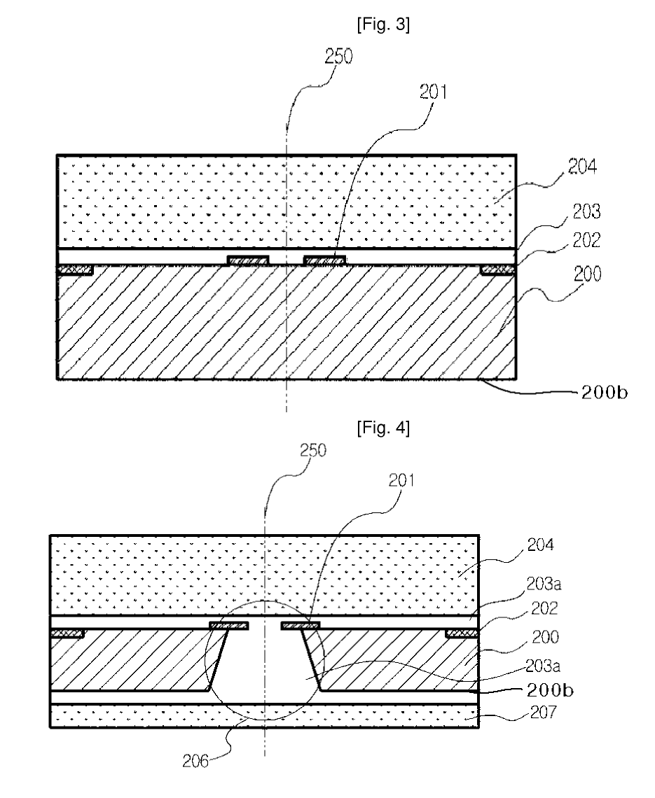

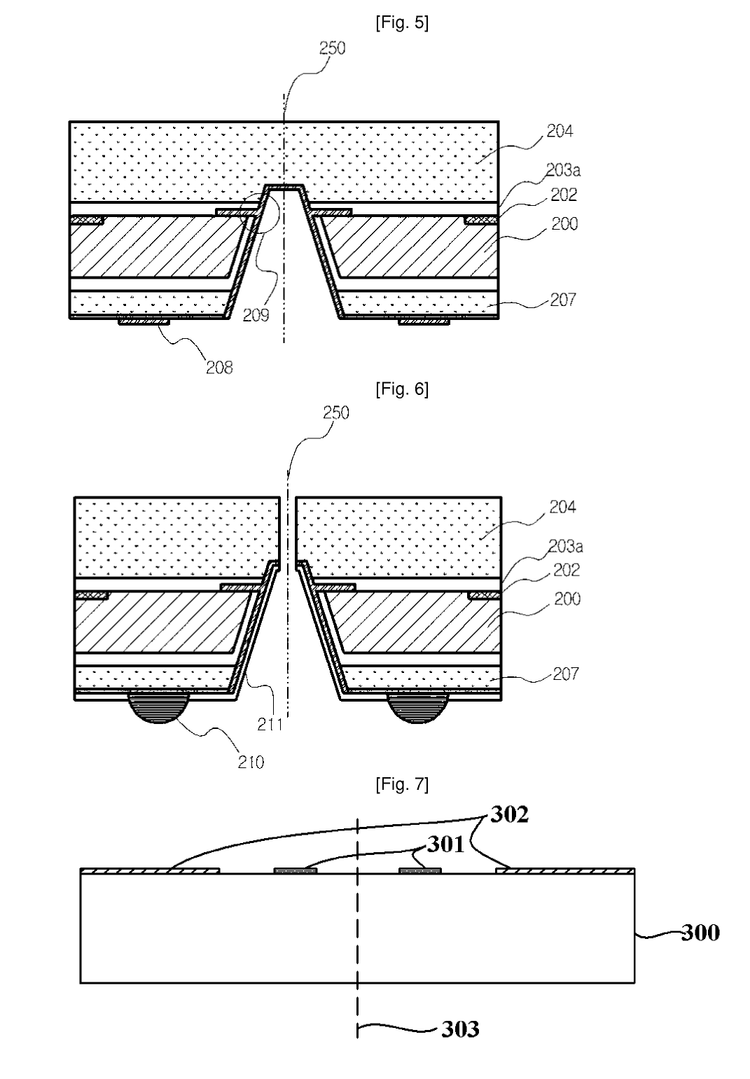

### MODE FOR THE INVENTION

These and other features, aspects, and advantages of preferred embodiments of the present invention will be more fully described in the following detailed description, taken accompanying drawings.

FIGS. 7 to 16 are cross-sectional views showing a method of wafer level packaging of a complementary metal oxide semiconductor (CMOS) image sensor using silicon via contacts in accordance with the preferred embodiment of the present invention.

Referring to FIG. 7, through a predetermined manufacturing process, a plurality of electrode pads 301 for an electric connection to an external circuit and a sensing unit 302 for image sensing are formed on a wafer 300. The wafer 300 includes a plurality of chips and a dicing process for dividing chips from one another for packaging is performed after completing the process for manufacturing chips. The chips are divided from one another along the cutting lane.

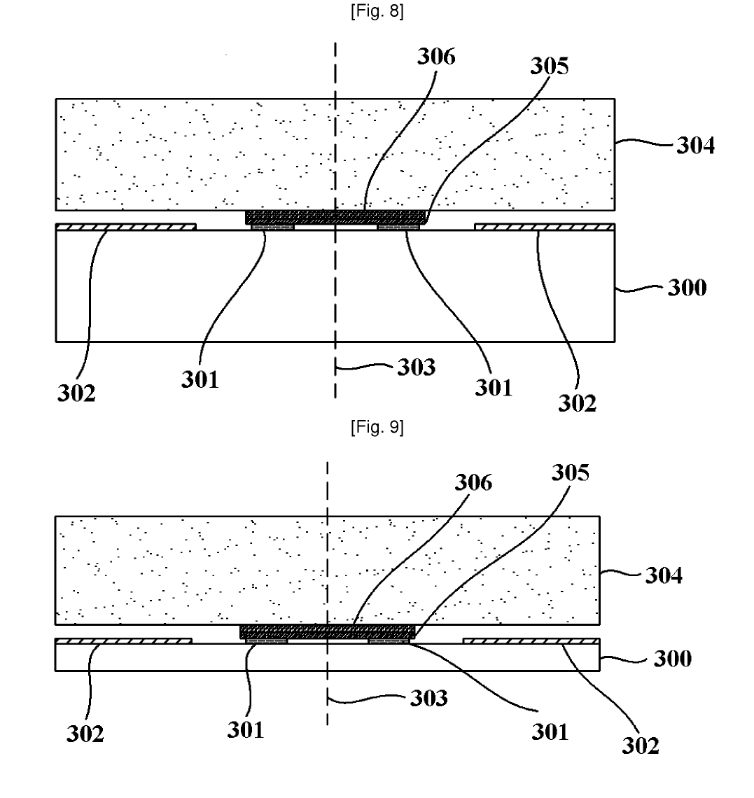

Next, referring to FIG. 8, a transparent substrate 304 is attached on the wafer 300. Desirably, the transparent substrate 304 is a glass substrate having a thickness ranging from 300 μm to 500 μm. For attaching the transparent substrate 304, an epoxy layer 305 is formed to extend over the electrode pads 301 on the both sides of the cutting lane 303. Further, a spacer 306 for securing space between the transparent substrate 304 and the wafer 300 is formed on the epoxy layer 305. Thereafter, the wafer 300 and the transparent substrate 304 are attached to each other. Therefore, during the following manufacturing processes, the sensing unit 302 and the electrode pads 310 formed on the wafer 300 are completely protected from any external foreign materials, resulting in a remarkably reduced defects.

Next, referring to FIG. 9, a back side of the wafere 300 is ground. The grinding process is performed in order to easily form a via hole in the wafer 300 in the subsequent process. Through the grinding process, the wafer 300 is ground, leaving a depth required for durability of the wafer 300. After the grinding process, a thickness of the wafer 300 is desirably 50 μm to 100 μm.

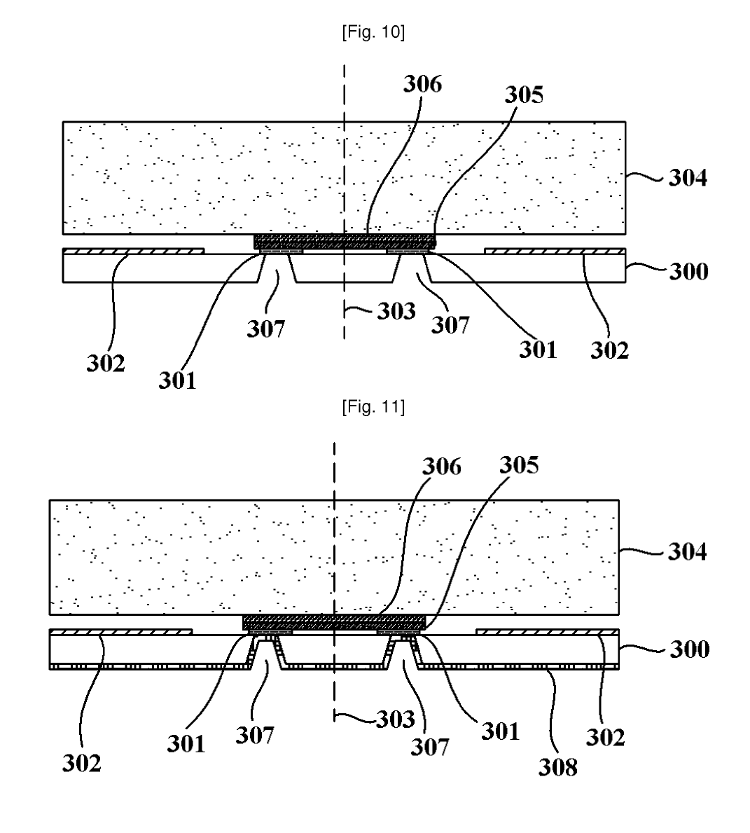

And then, referring to FIG. 10, via holes 307 are formed penetrating from aback side of the wafer 300 to lower parts of the electrode pads 301. The via hole 307 can be directly formed by means of dry etching using reactive ion etch (RIE). Otherwise, the via hole 307 can be made by forming a partially non-penetrated hole and then removing the remaining part of the wafer 300 using a dry etching or a wet etching. Herein, a diameter of the via hole 307 may range from several tens of μm to thousands of μm, and preferably within 200 μm. Although a shape of the via hole 307 is basically circle, the via hole 307 can also have various shapes such as a triangle, a quadrangle or a polygon. Further, a size of the penetrating hole formed at the back side of the wafer 300 can be larger, smaller or equal to that of underneath of the electrode 301.

Thereafter, referring to FIG. 11, a passivation layer 308 for insulating between electrodes is formed to cover etched surfaces of the via hole 307 and the back side of the wafer 300. The passivation layer 308 is desirably an oxide layer or a nitride layer. The passivation layer 308 is desirably oxidized by nitric acid solution deposited using low-temperature plasma enhanced chemical vapor deposition (PECVD).

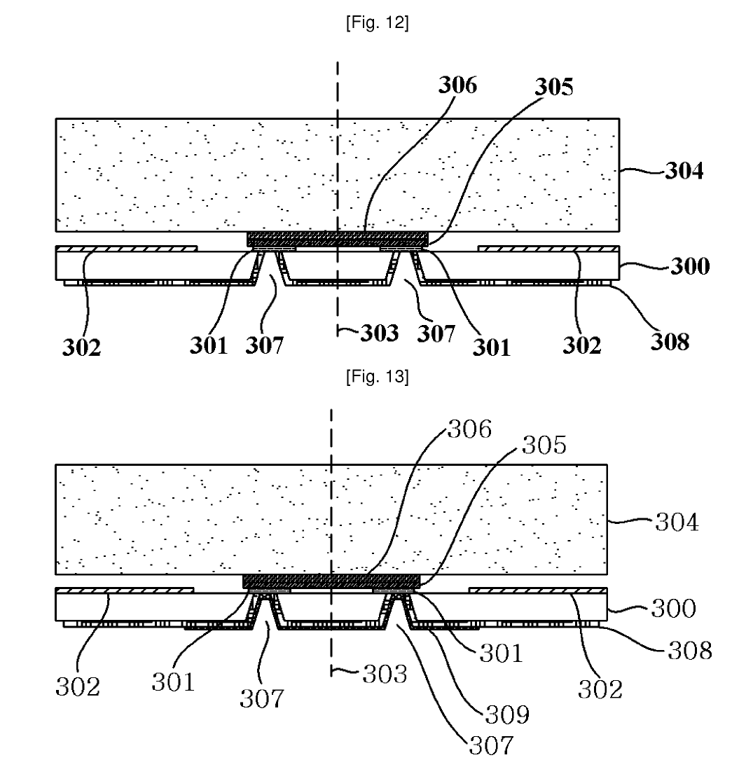

Next, referring to FIG. 12, the passivation layer 308 deposited on the bottom part of the via hole 307, i.e., the underneath of the electrode pad, is removed so that the electrode pads 301 are exposed.

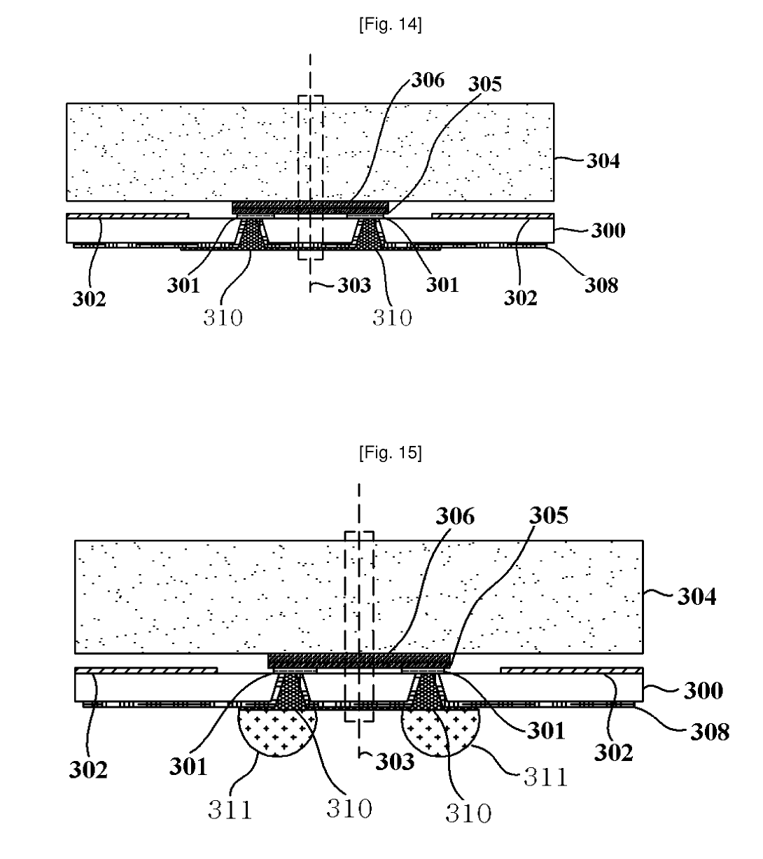

Sequentially, referring to FIGS. 13 and 14, after a seed layer 309 is formed inside the via hole 307 using a sputtering process, a via contact 310 is formed using a plating process or a printing process with solder paste. Herein, any conductive materials including conductive metals such as Au, Ag, Cu, Al, Ni, Cr and W or alloys thereof can be used.

Thereafter, referring to FIG. 15, a solder bump 311 is formed on the region where the via contact 310 is formed on the back side of the wafer 300. Although any conductive material can be used as the solder bump 311, the solder bump 311 is desirably Cu, Au, an alloy of Ni/Au or an alloy of Sn/Au.

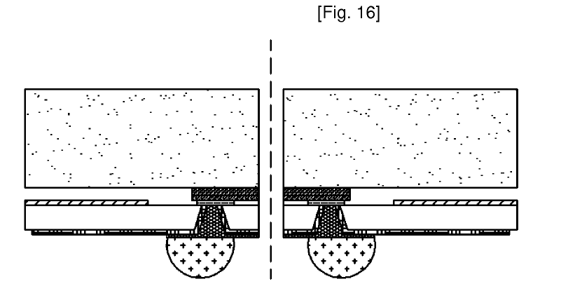

Finally, referring to FIG. 16, chips are separated from one another by dicing the completed wafer 300 and the transparent substrate 304 along the cutting lane 303.

Through the above-mentioned processes in accordance with the preferred embodiment of the present invention, an image sensor chip is completed. Thereafter, the separated image sensor chip is connected to an external circuit by being attached to an FPC or a printed circuit board through a solder bump formed on a back side of a wafer. Thereafter, an image device such as a camera is completed by assembling a lens and a lens housing.

While the present invention has been described with respect to certain preferred embodiments, it will be apparent to those skilled in the art that various changes and modifications may be made without departing from the scope of the invention as defined in the following claims.

### INDUSTRIAL APPLICABILITY

By using silicon via contacts, the wafer level package of a CMOS image sensor in accordance with the present invention has advantages as follows: at first, a via contact connected from a back side of a wafer to an electrode pad can be easily formed on a front side of the wafer where image sensing elements including a sensing unit and the electrode pads are formed; secondly, a decrease in production yield due to the foreign materials coming into a sensing unit can be prevented by covering with a transparent substrate, and forming a solder bump on a via contact exposed on a back side of the wafer and then connecting it to an external circuit through the back side, which has no image sensing element; thirdly, a thickness of a completed image sensor module can be decreased by removing unnecessary part of the wafer; and fourthly, a chip scale package (CSP) of a semiconductor device including an image sensor, which has a tendency to be smaller, can be effectively embodied and, further, it can be applied to a multi chip module (MCM).

1. A method of wafer level packaging of a complementary metal-oxide semi-conductor (CMOS) image sensor, the method comprising the steps of:
attaching a transparent substrate to a front side of a wafer where image sensor elements including a plurality of electrode pads are formed;
grinding a back side of the wafer;
forming a via hole penetrating from the back side of the wafer to underneath of the plurality of electrode pads of the front side of the wafer;
forming a passivation layer on whole surfaces of the via hole and the back side of the wafer;
removing the passivation layer formed on the electrode pad;
forming a via contact on the via hole;
forming a solder bump on the via contact of the back side of the wafer; and
dicing the wafer and the transparent substrate.

2. The method as recited in claim 1, before the step of attaching the transparent substrate, further comprising the steps of:
forming an epoxy layer to extend over the electrode pads in the both sides of a cutting lane; and
forming a spacer on an upper part of the epoxy layer.

3. The method as recited in claim 1, wherein the via contact forming step further includes the steps of:
forming a seed layer in the via hole by sputtering; and
filling the via hole with metal by printing of solder paste or plating the metal on a metal layer in the via hole.

4. The method as recited in claim 1, wherein a thickness of the transparent substrate is ranging from 300 μm to 500 μm.

5. The method as recited in claim 1, wherein a thickness of the wafer is ranging from 50 μm to 100 μm after the grinding step.

6. The method as recited in claim 1, wherein the via hole is directly formed by dry etching using a reactive ion etch (RIE) or, after a partially non-penetrated hole is formed, the via hole is formed by removing the remaining part of the wafer which is not penetrated using a dry etching or a wet etching.

7. The method as recited in claim 1, wherein the passivation layer is an oxide layer or a nitride layer formed using oxidation in a nitric acid solution or low-temperature plasma enhanced chemical vapor deposition (PECVD).

8. The method as recited in claim 1, wherein the via contact is made of one conductive metal selected from a group consisting of Au, Ag, Cu, Al, Ni, Cr, W and the like or alloys thereof.

9. The method as recited in claim 1, wherein the solder bump is one of Cu, Au, an alloy of Ni/Au or an alloy of Sn/Au.

10. A wafer level package of a CMOS image sensor, comprising:
a wafer where image sensor elements including a plurality of electrode pads are formed;
a transparent substrate attached to a front side of the wafer;
a via hole formed from a back side of the wafer to underneath of a plurality electrode pads of the front side of the wafer;
a passivation layer formed on a remaining portion except the lower part of the electrode pads in the via hole and whole of the back side of the wafer;
a via contact formed in the via hole; and
a solder bump formed on the via contact of the back side of the wafer.

11. The wafer level package of a CMOS image sensor as recited in claim 10, further comprising an epoxy layer and a spacer between the front side of the wafer and the transparent substrate.

12. The wafer level package of a CMOS image sensor as recited in claim 10, wherein a thickness of the transparent substrate ranges from 300 μm to 500 μm.

13. The wafer level package of a CMOS image sensor as recited in claim 10, wherein a thickness of the wafer ranges from 50 μm to 100 μm.

14. The wafer level package of a CMOS image sensor as recited in claim 10, wherein the passivation layer is made of an oxide layer or a nitride layer.

15. The wafer level package of a CMOS image sensor as recited in claim 10, wherein the via contact is made of one conductive metal selected from a group consisting of Au, Ag, Cu, Al, Ni, Cr, W or alloys thereof.

16. The wafer level package of a CMOS image sensor as recited in claim 10, wherein the solder bump is one of an alloy of Cu, Au, Ni/Au or an alloy of Sn/Au.
